(19) United States
(12) Patent Application Publication
(10) Pub. No.: US 2009/0317547 A1
(43) Pub. Date: Dec. 24, 2009

(54) CHEMICAL VAPOR DEPOSITION SYSTEMS AND METHODS FOR COATING A SUBSTRATE

(75) Inventor: Thomas Strangman, Prescott, AZ (US)

Correspondence Address: HONEYWELL INTERNATIONAL INC.;PATENT SERVICES, 101 COLUMBIA ROAD, P O BOX 2245, MORRISTOWN, NJ, 07962-2245, US

(73) Assignee: Honeywell International Inc., Morristown, NJ (US)

(21) Appl. No.: 12/141,506

(22) Filed: Jun. 18, 2008

(51) Int. Cl. C23C 16/52

(52) U.S. Cl. 427/248.1; 118/710

(57) ABSTRACT

Chemical vapor deposition systems and methods of coating a substrate are provided. The method includes evacuating a processing chamber to a threshold pressure. The substrate and the processing chamber are heated to a first processing temperature. A first pellet having a vaporization temperature that is below the first processing temperature is dispensed into the processing chamber and exposed to the first processing temperature within the processing chamber to vaporize the first pellet into a first processing vapor to produce a pressure change from the threshold pressure to a first pressure to cause the first processing vapor to flow through the processing chamber and onto the substrate. The substrate is exposed to the first processing vapor for a predetermined time.

### TECHNICAL FIELD

The inventive subject matter generally relates to coatings on components, and more particularly relates to forming coatings on components by chemical vapor deposition processes.

### BACKGROUND

Chemical vapor deposition processes are routinely used to deposit various materials onto various types of substrates for the formation of coatings. For example, protective aluminide diffusion coatings made up of one or more elements, such as Al, Si, and/or Hf, Zr, Y, Ce, La, and the like may deposited on substrates that are conventionally used in gas turbine engine components, such as airfoils. Typical substrates may be made of nickel and/or cobalt base superalloys. In any event, chemical vapor deposition processes generally occur in a chemical vapor deposition apparatus that includes a furnace in fluid communication with one or more processing gas sources. The furnace may include a retort that defines a chamber for receiving the substrate and that is in fluid communication with the processing gas sources. The retort is typically surrounded by a heater for elevating the internal temperatures of the chamber, and hence, the substrate, to suitable reaction temperatures.

The processing gas may be introduced into the chamber from an external tank or process gas generator via a gas connection line. In such case, an inert gas source may also be provided that provides an inert gas to the processing gas source upstream of the chamber. In this way, the inert gas may carry the processing gas into the chamber to flow over the substrate. In other configurations, the processing gas source is formed inside the chamber of the retort. For instance, a precursor material may be disposed in the chamber and may be formulated to emit the processing gas when heated to the suitable reaction temperature. After the processing gas is in the chamber, the elevated temperatures may serve as a thermal catalyst to promote reaction between the processing gas and a surface of the substrate to transform a portion of the substrate surface into a portion of the coating. Subsequently, any excess gases may be exhausted from the reactor to thereby maintain a continuous gas flow over the substrate.

Although the aforementioned chemical vapor deposition apparatus and processes form adequate coatings in most situations, they may be improved. In particular, apparatus that have processing gases delivered from external sources may include relatively complex systems having multiple processing and inert gas connection lines that join the gas sources to the retort chamber. Each gas connection line may be connected to pressure gauges, temperature gauges, and other components that may increase the complexity of the system. As a result, these types of systems may be relatively expensive to maintain and relatively difficult to repair. Apparatus having resident precursor materials disposed in the retort may be simpler in design. However, undesirable phases may be formed on component surfaces as the retort chamber is heated.

Accordingly, it is desirable to have an improved chemical vapor deposition apparatus that is simple in design and relatively inexpensive to maintain. Additionally, it is desirable for the apparatus to be capable of forming high quality coatings on a substrate. In addition, it is desirable to have a process that may be used to form coatings on external and internal surfaces of a substrate. Furthermore, other desirable features and characteristics of the inventive subject matter will become apparent from the subsequent detailed description of the inventive subject matter and the appended claims, taken in conjunction with the accompanying drawings and this background of the inventive subject matter.

### BRIEF SUMMARY

Chemical vapor deposition systems and methods for coating a substrate are provided.

In an embodiment, by way of example only, a chemical vapor deposition system for coating a substrate includes a pellet dispenser housing, a pellet dispenser, a pellet dispensing conduit, a processing chamber, a pressure sensor, a heater, an exhaust conduit, an exhaust valve, and a controller. The pellet dispenser housing is capable of being maintained at a maintenance temperature. The pellet dispenser is disposed within the pellet dispenser housing and is adapted to receive a first pellet therein. The pellet dispenser is also configured to dispense the first pellet. The pellet dispensing conduit is in communication with the pellet dispenser and is adapted to receive the first pellet therefrom. The processing chamber is in communication with the pellet dispensing conduit and is adapted to contain the substrate. The pressure sensor is in flow communication with the processing chamber and is adapted to sense a pressure within the processing chamber. The heater surrounds at least a portion of the processing chamber and is adapted to heat the processing chamber and the substrate to a processing temperature that is above the pellet vaporization temperature. The exhaust conduit is in flow communication with the processing chamber and includes an outlet. The exhaust valve is disposed within the exhaust conduit and is adapted to move between a closed position to prevent flow through the outlet and an open position to allow flow through the outlet. The controller is operatively coupled to the pressure sensor to receive sensed pressure data therefrom and to the valve to supply commands thereto. When the processing chamber pressure is below a threshold pressure, the pellet dispenser dispenses the first pellet into the pellet dispensing conduit and the first pellet is exposed to the processing temperature of the processing chamber, the first pellet changes into a first processing vapor to produce a pressure change in the processing chamber to a first pressure that is above the threshold pressure causing the first processing vapor to flow in the processing chamber and over the substrate. After a predetermined amount of time, the controller supplies a command to the exhaust valve to move toward the open position, and when the pressure sensor senses that the pressure is substantially equal to or below the threshold pressure, the controller supplies a command to the exhaust valve to move toward the closed position.

In another embodiment, by way of example only, a method of coating a substrate is provided. The method includes evacuating a processing chamber to a threshold pressure. The substrate and the processing chamber are heated to a first processing temperature. A first pellet is dispensed into the processing chamber, the first pellet having a vaporization temperature that is below the first processing temperature. The first pellet is exposed to the to the first processing temperature within the processing chamber that is above the vaporization temperature to vaporize the first pellet into a first processing vapor to produce a pressure change in the processing chamber from the threshold pressure to a first pressure to cause the first processing vapor to flow through the processing chamber and onto the substrate. The substrate is exposed to the first processing vapor for a predetermined time. After the step of exposing the substrate, a valve in an exhaust conduit in communication with the processing chamber is moved toward an open position. The valve is moved toward a closed position, when the pressure sensor senses a pressure in the processing chamber is below the threshold pressure.

### BRIEF DESCRIPTION OF THE DRAWINGS

The inventive subject matter will hereinafter be described in conjunction with the following drawing figures, wherein like numerals denote like elements, and

FIG. 1 is a simplified cross-sectional view of a chemical vapor deposition system, according to an embodiment;

FIG. 2 is a simplified top view of a pellet dispenser, according to an embodiment;

FIG. 3 is a flow diagram of a method of coating a substrate, according to an embodiment; and

FIG. 4 is a flow diagram of a method of coating a substrate, according to another embodiment.

### DETAILED DESCRIPTION

The following detailed description is merely exemplary in nature and is not intended to limit the inventive subject matter or the application and uses of the inventive subject matter. Furthermore, there is no intention to be bound by any theory presented in the preceding background or the following detailed description.

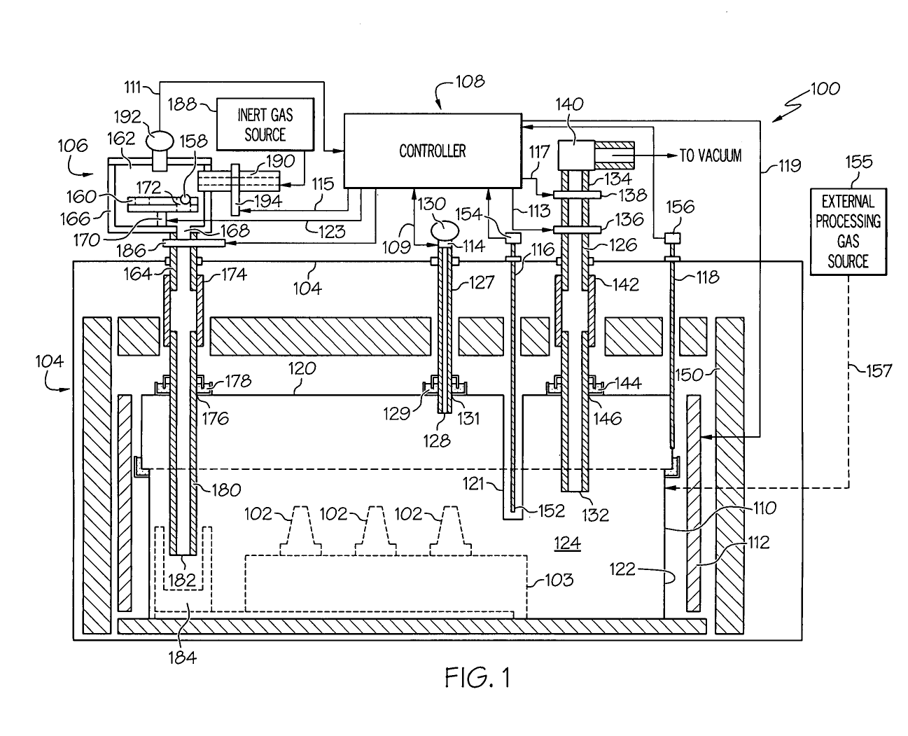

FIG. 1 is a simplified, cross-sectional view of a chemical vapor deposition system 100, according to an embodiment. The chemical vapor deposition system 100 is configured to perform a chemical vapor deposition process on a substrate 102 for the formation of at least a portion of a coating thereon. In an embodiment, the substrate 102 may be an engine component, such as an airfoil, a turbine blade, a turbine, a turbine nozzle, or another engine component on which a protective coating may be formed.

The chemical vapor deposition system 100 may be a remote, stand alone apparatus or an in-situ module that is incorporated into a processing system. The chemical vapor deposition system 100 shown in FIG. 1 is an example of a stand alone apparatus. Generally, the chemical vapor deposition system 100 is configured to employ pellets capable of being vaporized when exposed to a processing temperature to form a processing vapor, which may deposit on or react with a surface of the substrate 102. Thus, in an embodiment, the chemical vapor deposition system 100 may include a vacuum furnace assembly 104, a pellet dispensing assembly 106, and a system controller 108.

The vacuum furnace assembly 104 is adapted to receive the substrate 102 and to provide a controlled environment in which deposition on the substrate 102 may occur. In this regard, the vacuum furnace assembly 104 may include a retort 110, a heater 112, a pressure sensor 114, and one or more temperature sensors 116, 118. The retort 110 may be made up of a separable lid section 120 and an enclosure section 122 that are configured to mate with each other and together to define a processing chamber 124. The processing chamber 124 may be sized for containing one or more substrates 102, which may be disposed on a platform 103 (shown in phantom), in some embodiments, or on another surface in the processing chamber 124. In an embodiment, as shown in FIG. 1, three substrates may be included, however the processing chamber 124 may be alternatively configured to house fewer or many more substrates (e.g., at least fifty substrates) depending on the particular dimensions of the retort sections 120, 122. In an example, the processing chamber 124 may have a diameter in a range of between about 10 cm to about 100 cm, and a depth in a range of between about 5 cm to about 50 cm. In other embodiments, the processing chamber 124 may have larger or smaller dimensions. Moreover, although the lid section 120 and the enclosure section 122 in FIG. 1 appear to form a cylindrical processing chamber 124, the sections 120, 122 may be alternatively shaped to provide a rectangular box-shaped, dome-shaped, spherical-shaped, or other shaped processing chamber 124.

As noted above, the processing chamber 124 may be controlled to provide an environment within which the chemical vapor deposition processing may occur. In an embodiment, the processing chamber 124 may be evacuated and pressurized to provide an environment having an initial, desired pressure. For example, the initial pressure may be one suitable for providing a vacuum environment. To ensure that the processing chamber 124 is maintained at the initial pressure, the pressure sensor 114 and an exhaust conduit 126 may be included. The pressure sensor 114 may be connected to the processing chamber 124 by a conduit 127, which is disposed at least partially within the processing chamber 124. In an embodiment, the conduit 127 for the pressure sensor 114 may extend through an opening 131 in the lid section 120 and may have a conduit end opening 128 that is disposed within the processing chamber 124 to thereby transmit the pressure within the chamber 124 to the pressure sensor 114. A pressure indicator end 130 of the pressure sensor 114 may reside on an exterior of the furnace assembly 104 to provide a pressure reading, in an embodiment. To prevent leakage from the processing chamber 124, a seal 129 may inhibit gas flow between the exterior of the pressure sensor conduit 127 at the opening 131 in the lid section 120. The seal 129 may comprise a sand seal, as shown in FIG. 1, or may be another type of sealing means, such as by welding. The pressure sensor 114 may be operatively coupled to the system controller 108, which may receive an indication of the sensed pressure and may be adapted to determine whether to increase or decrease the pressure of the processing chamber 124, if the pressure therein exceeds or is below a threshold pressure. The threshold pressure may be substantially equal to (e.g., ±0.05 atm) the initial pressure, in an embodiment. In other embodiments, the threshold pressure may be above or below the initial pressure. A small purge flow of an inert gas (not shown) may be injected into the pressure sensor 114 and conduit 127 to inhibit vapor from the processing chamber from entering the pressure sensor 114.

Gases within the processing chamber 124 may be exhausted from the exhaust conduit 126. Depending on a step of the chemical vapor deposition process, the gases may include processing vapor and/or inert or reducing gases. In any case, the exhaust conduit 126 may extend through the lid section 120 and may include an inlet end 132 adapted to be disposed within the processing chamber 124 and an outlet end 134 that may reside outside of the furnace assembly 104. To control the exhaustion of the gases from the processing chamber 124, the outlet end 134 of the exhaust conduit 126 may include one or more components. In one example, a first valve 136 may be disposed in the exhaust conduit 126. The first valve 136 may be adapted to move between an open position and a closed position, in response to command signals from the system controller 108. As used herein, an “open position” may be defined as a valve position allowing flow through about 100% of a flow area, such as an outlet of the exhaust conduit 126. A “closed position” may be defined as a valve position allowing substantially no flow across a flow area, such as the outlet of the exhaust conduit 126. The first valve 136 may be a gate-type valve and may be disposed outside of the furnace assembly 104, in an embodiment.

In accordance with another embodiment, the outlet end 134 alternatively or additionally may include a second valve 138 that may be configured to continuously bleed gases out of the processing chamber 124. For example, the second valve 138 may be a bleed-type valve including a pinhole orifice adapted to allow gas to bleed therethrough in a controlled manner. In such case, the pinhole orifice may have a fixed diameter, allowing gas to flow through at all times. In another embodiment, the orifice may be adapted to transition between an open position and a closed position or between various partially open positions (e.g., less than 100% flow but more than 0% flow across a flow area) to control a flow of the gas. In another embodiment, a filter 140 may be included in flow communication with the outlet end 134 of the exhaust conduit 126 and the vacuum pump (not shown) The filter 140 may be adapted to capture one or more particles that may be in the gas to prevent the particles from exiting the system 100. For example, the filter 140 may trap unwanted particles, such as halide salts, and corrosive gases (e.g., hydrogen chloride), to prevent the particles and corrosive gases from being vented into the atmosphere. In an embodiment, the filter 140 may be a cold-trap condenser that condenses any escaping processing vapor (e.g, halide) into a liquid or a solid to thereby prevent corrosive constituents in the vapor from venting. In another embodiment, the filter 140 may include a fine mesh screen that is capable of trapping particles. In still another embodiment, the filter 140 may include a material that reacts with the escaping processing vapor to transform the vapor into a solid or liquid that is trapped in the filter 140.

The path between the processing chamber 124 and the exhaust conduit 126 may be substantially sealed. In such case, a bellows 142 and a seal 144 may be employed. In an embodiment, the bellows 142 may be mounted to the lid section 120 of the retort 110 and adapted to receive a portion of the exhaust conduit 126. The bellows 142 may be used to guide the exhaust conduit 126 into an opening 146 designated for receiving the inlet end 132 of the conduit 126. Additionally, as shown in FIG. 1, the seal 144 may be included around the opening 146. In an embodiment, the seal 144 may be a sand seal. The seal 144 inhibits process gas vapor from the retort 110 from leaking into the vacuum furnace assembly 104 space that contains the heater 112 and insulation 150. A separate vacuum pump (not shown) may evacuate the space within the vacuum furnace assembly 104 that contains the heater 112 and insulation 150.

In another embodiment, the processing chamber 124 may be heated and thus, the heater 112 may be disposed around at least a portion of the processing chamber 124. In an embodiment, the heater 112 may surround an entirety of the retort 110. In an embodiment, heater 112 may have more than one independently-controlled zones. In another embodiment, the heater 112 may surround substantially all of the enclosure section 122 of the retort 110. In still another embodiment, the heater 112 may surround a portion of the retort 110, such as a portion of the enclosure section 122. In such case, in an embodiment, insulation 150 may be included around other portions of the retort 110 to slow heat loss from the processing chamber 124 to the outer structural walls of the vacuum furnace assembly 104 during and/or after heating occurs. External walls of the vacuum furnace assembly 104 may be cooled; e.g., by water passages within the walls (not shown). The heater 112 may be adapted to heat the processing chamber 124 to temperatures in a range of between about 800° C. to about 1150° C., in an embodiment. In other embodiments, the temperatures may be less or greater.

To determine whether the processing chamber 124 has been heated to a desired temperature, temperature sensors 116, 118 may be included. In an embodiment, the temperature sensors 116 and 118 may be thermocouples. A load temperature sensor 116 may extend into a well 121 in the lid section 120 to thereby sense a temperature of the processing chamber 124, in an embodiment. In another embodiment, the load temperature sensor 116 may have an end 152 that is adapted to be positioned adjacent to the substrates 102 and to sense the temperatures thereof. In yet another embodiment, an additional external temperature sensor 118 may be positioned against a wall of the retort 110 to sense a temperature of the retort wall. In any case, the temperature sensors 116, 118 each may include readout faces 154, 156 providing readings of temperatures at corresponding locations, and/or each may be operatively coupled to the system controller 108, which may be coupled to the heater 112 to produce commands to increase or decrease heat production based on the sensed temperatures.

The pellet dispensing assembly 106 is adapted to maintain one or more pellets 158 in an environment in which vaporization of the pellets is prevented. In this regard, the pellet dispensing assembly 106 includes a pellet dispenser 160 for containing the pellets 158, a pellet chamber 162 within which the pellet dispenser 160 is disposed, and a pellet dispensing conduit 164 that provides a path from the pellet chamber 162 to the processing chamber 124. One or more of the pellets 158 may comprise one or more solid phase materials having a vaporization temperature that is lower than a processing temperature and that, when exposed to a temperature equal to or above the vaporization temperature (such as the processing temperature) vaporizes into a processing vapor that may be deposited onto or reacted with a surface of a substrate. For example, the pellets 158 may include substantially a single material. Alternatively, the pellets 158 may include a mixture of materials. In either case, the pellets 158 may include a plurality of particles comprising the one or more materials that have been compacted into a desired shape. In another embodiment, the pellets 158 may be a solid form, such as a frozen form, of the one or more materials, wherein the one or more materials may be a liquid at room temperature (e.g., about 22° C.). In another embodiment, one or more of the pellets 158 may comprise a solid outer capsule of a first material within which a solid phase, for example powder form, of a second material is disposed. In still another embodiment, the second material may alternatively comprise a liquid. Suitable materials include, but are not limited to metal halides, such as hafnium chloride and aluminum chloride, or ceramic capsules, such as alumina or zirconia, that are filled with a desired amount of halide powder or a frozen halide, such as silicon bromide. In other embodiments, each of the pellets may be a mixture of the aforementioned materials. In yet other embodiments, all of the pellets 158 may have substantially the same formulation. In still yet other embodiments, one or more of the pellets 158 may have different formulations from each other.

To ensure that each pellet 158 will substantially entirely vaporize when exposed to the processing temperature, each pellet 158 may be relatively small in dimension and relatively lightweight. In an embodiment, the pellets 158 may have diameters in a range of between about 2 mm to about 5 mm. Additionally, the pellets 158 may have a weight in a range of between about 50 mg to about 500 mg, according to an embodiment. In another embodiment, the diameters and the weight ranges may be greater or less than the aforementioned ranges. In other embodiments, the diameters may be larger for pellets 158 of a lighter weight material, or may be smaller for pellets 158 of a heavier material. The pellets 158 may be substantially uniformly sized (e.g., within ±0.5 mm) in an embodiment, however this may not be the case in other embodiments. In still other embodiments, the pellets 158 may substantially uniform in weight (e.g., within ±0.5 mg); however, in other embodiment, they may not be. In still yet other embodiments, the pellets 158 may be substantially uniform in shape. For example, the pellets 158 may be generally spherical to promote more uniform vaporization during the chemical vapor deposition process. In other examples, the pellets 158 may have other shapes, such as ovular, cylindrical, or any other three-dimensional shape. In still other examples, the pellets 158 may not be substantially uniform in shape. In an embodiment, pellets 158 having a first formulation may be a first shape, while pellets having a second formulation may be a second different shape. Alternatively, some of the pellets 158 may have different shapes, but similar diameters and weights.

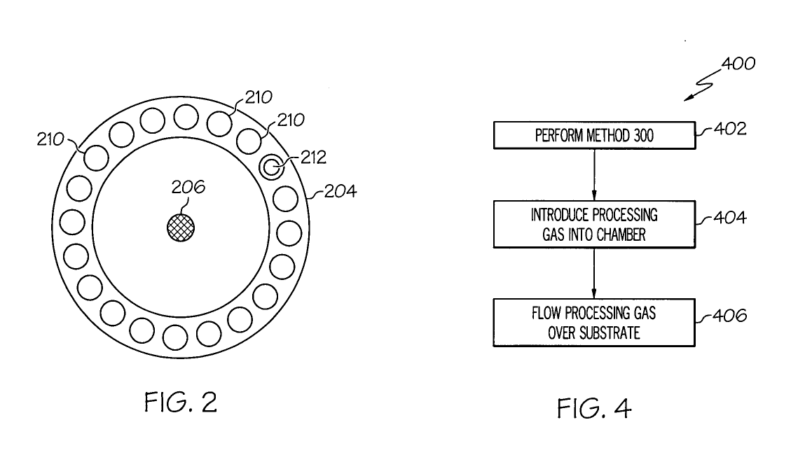

In any case, the pellet dispenser 160 is adapted to contain one or more of the pellets 158 and to dispense one or more of the pellets 158 into the pellet dispensing conduit 164 in response to an output signal from the system controller 108. FIG. 2 is a top view of a pellet dispenser 200, according to an embodiment. Here, the pellet dispenser 200 is a carousel-type device including a disk 204 adapted to rotate about a shaft 206. The disk 204 may have an outer diameter that is between about 5 cm to about 50 cm and a disk thickness of between about 1 mm and about 10 mm, in an embodiment. In other embodiments, the disk dimensions may be larger or smaller than the aforementioned ranges. In any case, the disk 204 may include a plurality of wells 210 for containing a corresponding number of pellets 212 so that the pellet dispenser 200 may dispense a sequence of pellets 212 therefrom. If desired, more than one pellet 212 may be inserted into a well 210. Each well 210 may have a diameter of between about 2 mm to about 12 mm and a depth of between about 1 mm to about 10 mm. However, the particular dimensions of the well 210 may depend on a size and number of pellets 212 to be included therein.

Returning to FIG. 1, the pellet dispenser 160 is disposed in the pellet chamber 162, which is defined by a pellet dispenser housing 166 that is adapted to receive the pellet dispenser 160 therein and is capable of being evacuated and pressurized to a desired pressure and maintained at a desired temperature. In an embodiment, the particular dimensions of the pellet dispenser housing 166 may depend on the particular dimensions and the configuration of the pellet dispenser 160. For example, if the pellet dispenser 160 has dimensions within the ranges mentioned above, the housing 166 may have a diameter in a range of between about 10 cm to about 60 cm, and a depth in a range of between about 2 cm to about 10 cm. In other embodiments, the housing 166 may have dimensions that are larger or smaller than the aforementioned ranges. As mentioned above, the pellet dispenser housing 166 may be evacuated or pressurized to a desired pressure. In an embodiment, the pellet dispenser housing 166 may be maintained at vacuum, or in another embodiment, the pellet dispenser housing 166 may be pressurized with an inert or reducing gas at a pressure that slightly exceeds (e.g., by 0.05 atm) the pressure within the processing chamber 124 when the pellet is dispensed. The slightly higher pressure within the pellet dispenser 160 may aid in inhibiting backflow of hot gas from the processing chamber 124. The desired temperature in pellet dispenser 160 may be a temperature at which the pellets 158 will not vaporize and that is preferably well below the processing temperature; e.g., the desired temperature may be room temperature (e.g., 22° C.). In another embodiment in which frozen capsules are employed, the desired temperature may be a temperature that is equal to or less than the freezing temperature of the pellets 158.

The pellet dispenser 160 dispenses the pellets 158 directly into the dispensing conduit 164 via an opening 168 in the housing 164, in an embodiment. In an example, the pellet dispenser 160 may rotate about a shaft 170 and as a well 172 of the dispenser 160 passes over an inlet to the pellet dispensing conduit 164, the pellet 158 may be received by the conduit 164. The pellet dispensing conduit 164 extends into the furnace assembly 104 to provide entry into the processing chamber 124. To substantially seal the path between the pellet chamber 162 and the processing chamber 124, a bellows 174 may be mounted to the lid section 120 of the retort 110. The bellows 174 may be adapted to receive a portion of the pellet dispensing conduit 164 to thereby guide the pellet dispensing conduit 164 to a designated opening 176. Additionally, as shown in FIG. 1, a seal 178 may be included and may surround the opening 176 in the lid section 120. In an embodiment, the seal 178 may be a sand seal, as shown, or alternatively, may be a weld, or other suitable seal that may be capable of sealing when heated to chemical vapor deposition processing temperatures (e.g., temperatures greater than about 800° C.). An end 180 of the pellet dispensing conduit 164 may be disposed within the processing chamber 124 to deliver a pellet (e.g., pellet 158) or processing vapor formed from a vaporized pellet thereto. In an embodiment, an opening 182 on the end 180 may communicate with a container 184 positioned within the processing chamber 124. The container 184 may be included to receive any unvaporized portions of the pellets 158. In an embodiment, the container 184 may comprise a sponge material that may be capable of withstanding the processing temperatures. In another embodiment, the sponge may comprise a metallic or ceramic material. According to another embodiment, the container 184 may be an alumina or ceramic sponge basket.

To inhibit backflow of the vapor in the processing chamber 124 into the pellet chamber 162, a valve 186 may be used to control flow communication between the pellet dispenser housing 166 and the processing chamber 124, in an embodiment. For example, the valve 186 may be a shutter or a gate valve that is disposed in the pellet dispensing conduit 164 and is in communication with the system controller 108. The valve 186 may be configured to move between an open position, during which one or more pellets 158 may be dispensed into the pellet dispensing conduit 164, and thus, the processing chamber 124 for vaporization, and a closed position, to prevent backflow communication between the pellet dispenser housing 166 and the processing chamber 124. In another embodiment, an inert or reducing gas may be introduced into the pellet dispenser housing 166 to maintain a slightly higher pressure (e.g., about 0.05 atm higher) within the pellet dispenser housing 166 than exists inside the processing chamber 124 prior to opening the valve 186 to dispense a pellet 158. In this regard, an inert or reducing gas source 188 may be in fluid communication with the pellet dispenser housing 166 via a gas source conduit 190, and flow therethrough may be controlled by a valve 194 that operatively communicates with the system controller 108. The inert gas may also be used for purging the processing vapor or other gases (e.g., byproducts resulting from a reaction between the processing vapor and a surface of the substrate 102) from the processing chamber 124, when a cycle or a portion of a cycle of the chemical vapor process is completed. The inert or reducing gas source 188 may include any inert gas, such as argon, a reducing gas, such as hydrogen, and mixtures of hydrogen and an inert gas. In an embodiment, a pressure sensor 192 may be disposed within the pellet dispenser housing 166 so that the system controller 108 may detect a pressure of the housing 166 to thereby determine whether to move valves 186 and 194 to open or closed positions.

As alluded to above, the system controller 108 is adapted to control the vacuum furnace assembly 104 and the pellet dispensing assembly 106. In an embodiment, the system controller 108 receives output signals 109, 111 representing sensed pressure data from the pressure sensors 114, 192 that may be used to determine whether to provide one or more commands 113, 117 to the first or second valves 136, 138 of the exhaust conduit 126 or commands 115 to the gas source conduit valve 194 to the move to the open position, to the closed position, or in some embodiments, to a partially open position. The system controller 108 also receives sensed temperature data from the temperature sensors 116, 118 to determine whether to provide commands 119 to the heater 112 to turn on or turn off. In some embodiments, the system controller 108 may also be adapted to provide commands 123 to the pellet dispenser 160 to control a frequency at which the pellets 158 may be dispensed into the processing chamber 124. In another embodiment, the system controller 108 also may provide commands to the valve 186 that controls the flow of inert or reducing gas from the pellet dispenser 160 to the processing chamber 124.

The system controller 108 may include any one of numerous known general-purpose microprocessors or an application specific processor that operates in response to program instructions. In an embodiment, the controller 108 includes RAM (random access memory) and ROM (read only memory). The program instructions that control the controller 108 may be stored in either or both the RAM and the ROM. For example, operating system software may be stored in the ROM, whereas various operating mode software routines and various operational parameters may be stored in the RAM. It will be appreciated that this is merely exemplary of one scheme for storing operating system software and software routines, and that various other storage schemes may be implemented. It will also be appreciated that the controller 108 may be implemented using various circuits other than a programmable processor. For example, digital logic circuits and analog signal processing circuits could also or alternatively be used.

In some embodiments, the processing chamber 124 may be in flow communication with other components. For example, as shown in phantom in FIG. 1, the processing chamber 124 may be in flow communication with an external processing gas source 155 via a conduit. The external processing gas source 155 may be a conventional CVD gas generator, a bottled gas source, or another suitable processing gas source. In other embodiments, the processing chamber 124 may communicate with additional components.

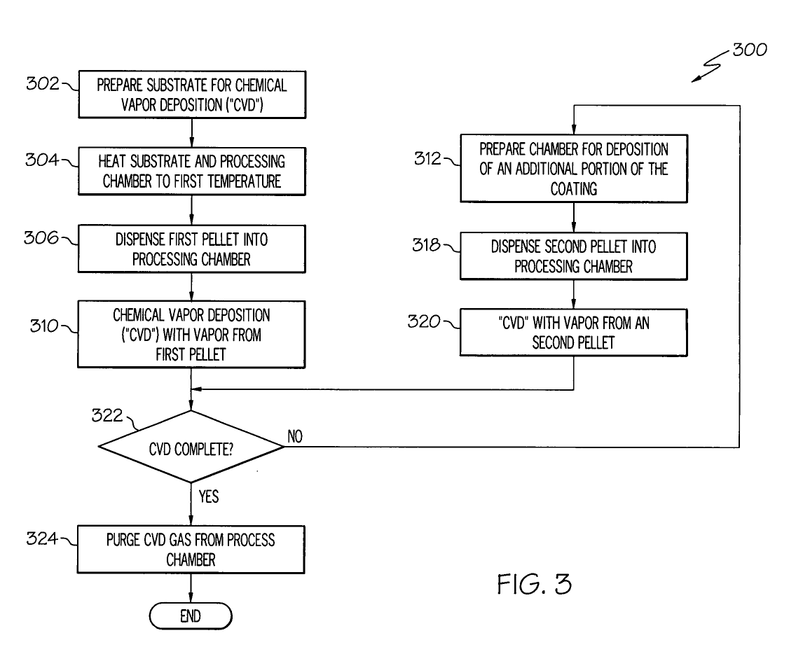

FIG. 3 is a flow diagram of a method 300 of coating a substrate, according to an embodiment. The method 300 may be performed using system 100, or another chemical vapor deposition system having similar capabilities. In an embodiment, a substrate is prepared for a chemical vapor deposition thereon, step 302. Preparation may include deposition of a constituent that is diffused with the substrate and subsequently incorporated into the CVD coating, such as a few microns of electroplated or sputtered platinum, depending on a particular composition of the coating. In another embodiment, the component may be mechanically prepared. In another embodiment, mechanical preparation may be performed on the substrate. Examples of mechanical preparation steps include, but are not limited to, grit blasting, pre-deposition machining and/or degreasing surfaces of the substrate in order to remove any oxidation, dirt or other contaminants. In another embodiment, surface preparation may occur and may include a fluoride ion cleaning process to remove oxides from the surfaces of the substrate. The fluoride ion cleaning process may be followed with a high-temperature vacuum cleaning process to remove excess fluoride remainder that may be on the substrate. In other embodiments, additional or different types and numbers of preparatory steps can be performed.

The substrate may then be placed in a processing chamber, and both are heated to a first processing temperature, step 304. The first processing temperature may be a temperature at which a material to be deposited onto the substrate may react with a surface thereof. In an embodiment, the first processing temperature may be in a range of between about 800° C. to about 1150° C. In another embodiment, the first processing temperature may be in a range of between about 900° C. to about 1050° C. In other embodiments, the first processing temperature may be less or greater than the aforementioned ranges, depending on, among other things, a chemistry of the material to be deposited, a duration over which the reaction may be allowed to occur, a chemistry of the substrate, an amount of material to be deposited onto the substrate, and an intended quality and/or desired property that deposited material is to impart on the substrate. In an embodiment, inert or reducing gas may be flowed through the processing chamber before and during heating to inhibit oxidation of the substrate surface. In another embodiment, the processing chamber is evacuated to a threshold pressure before or during heating. As used herein, the term “threshold pressure” may be defined as a pressure in the processing chamber that is suitable to inhibit backflow of a processing vapor into the pellet dispensing housing. In an embodiment, the threshold pressure may be less than or equal to the pressure within the pellet dispensing housing. In another embodiment, the threshold pressure may be a vacuum.

Substantially simultaneously with the step 304, a first pellet is maintained in a pellet chamber at a maintenance temperature that is below the vaporization temperature of the first pellet. In an embodiment, the maintenance temperature may be substantially equal to (e.g., within ±5° C.) room temperature (e.g., 22° C.). In another embodiment, the maintenance temperature may be a temperature that is below the freezing temperature of the pellet, if the first pellet is comprised of a material that is a liquid at room temperature.

In any case, the first pellet is dispensed into a pellet dispensing conduit that is in communication with the processing chamber, step 306. The first pellet may be formulated similarly to the pellets described above (e.g., pellets 158 in FIG. 1) having a vaporization temperature that is below the first processing temperature. For instance, the first pellet may comprise a metal halide, in an embodiment. In another embodiment, the metal halide may be selected from the group consisting of hafnium chloride, aluminum chloride, and silicon bromide. In another embodiment, the first pellet may comprise an alumina container filled with silicon bromide. In still other embodiments, the first pellet may comprise other materials formed into a pellet that may be typically employed during a chemical vapor deposition process. To dispense the first pellet into the pellet dispensing conduit, the pellet dispenser may rotate such that the first pellet is disposed over an opening into the pellet dispensing conduit and dropped into the conduit. A valve between the pellet dispenser and the processing chamber (e.g., valve 186) may open just before pellet dispensing and may close immediately after the pellet is dispensed. In order to avoid backflow of hot processing chamber gas, the pressure of inert or reducing gas within the pellet dispensing assembly may be maintained at a slightly higher pressure (e.g., about 0.05 atm above) than the threshold pressure within the processing chamber when the pellet is dispensed.

The dispensed first pellet falls through the conduit and into the processing chamber. The first pellet is vaporized into a first processing vapor upon exposure to the first processing temperature of the processing chamber.

Vaporization of the first pellet results in a pressure change within the processing chamber. The pressure change associated with pellet vaporization initiates the chemical vapor deposition step 310. In an embodiment, the pressure may change from the threshold pressure to a first pressure. For instance, the pressure change may be as little as 0.05 atm, or as large as 0.5 atm. In other embodiments, the pressure change may be larger or smaller. In any case, the pressure change causes the first processing vapor to flow throughout the processing chamber and onto the substrate. Because the substrate is heated to the first processing temperature, the first processing vapor and a surface of the heated substrate may react to form a first portion of the coating. In some embodiments, a reducing gas, such as hydrogen, an inert gas, such as argon, or a mixture of inert and reducing gas, may flow into the processing chamber after the pellet has been vaporized. In an embodiment, a reactive or carburizing gas, such as methane, may flow into the processing chamber before or after the pellet has been vaporized. In accordance with another embodiment, the components are exposed to the first processing vapor for an exposure period of 1 to 10 minutes, which provides the substrate with time to react with the first processing vapor. In another embodiment, the exposure period may be longer or shorter.

A determination may be made regarding whether the chemical vapor deposition process is completed, step 322. If so, the processing chamber may be purged of coating gases and cooled, step 324, and the process may end. If the coating process is not complete, the process may iterate as shown in FIG. 3. During the process, any number of pellets in a range of one to one hundred, for example, may be dispensed and vaporized. In another embodiment, the number of pellets that may be dispensed and vaporized may exceed one hundred.

In an embodiment, after sufficient time has elapsed to form the first portion of the coating in Step 310 and a determination is made that the CVD coating is not complete, Step 322, the processing chamber may be prepared for deposition of a second or additional portion of the coating, step 312. For example, the pressure within the processing chamber may be reduced to the threshold pressure. In an embodiment, if the controller determines that the pressure of the processing chamber is above a threshold pressure for dispensing the second pellet, a valve in an exhaust conduit in communication with the processing chamber may be moved toward the open position to allow a portion of the first processing vapor to be exhausted from the processing chamber and to decrease the pressure toward the threshold pressure. In another example, if the pressure sensor senses that the pressure of the processing chamber is substantially equal to or below the threshold pressure, the exhaust conduit valve may be moved toward the closed position. In another embodiment, the processing chamber may be purged of the first processing vapor and/or byproducts that may have resulted from the reaction between the first processing vapor and the surface of the substrate. Purging may occur by flowing the vapor and/or byproducts through the exhaust conduit, in an embodiment. According to another embodiment, an inert or reducing gas may be introduced into the processing chamber and flowed through the processing chamber to carry the residual process gas and/or byproducts to the exhaust conduit. In an embodiment, the temperature of the processing chamber may be increased or reduced to a second processing temperature for deposition of the next portion of the coating. In an embodiment, the second processing temperature may be equal to or greater than the first processing temperature. In other embodiments, the second processing temperature may be below the first processing temperature, but greater than the vaporization temperature.

When a second pellet is to be vaporized, it may be dispensed into the processing chamber, step 318. In one example, the second pellet may have a formulation that is different from the first pellet. In another embodiment, the second pellet may have a formulation that is substantially similar to the first pellet. After the second pellet is dispensed, it may vaporize into a second processing vapor when it is exposed to the second processing temperature.

Vaporization of the second (or additional) pellet results in a pressure change within the processing chamber. The pressure change associated with pellet vaporization initiates the chemical vapor deposition step 320. In an embodiment, the pressure may change from the threshold pressure to a second pressure. For instance, the pressure change may be as little as 0.05 atm, or as large as 0.5 atm. In other embodiments, the pressure change may be larger or smaller. In any case, the pressure change causes the second processing vapor to flow throughout the processing chamber and onto the substrate. Because the substrate is heated to the processing temperature, the second processing vapor and a surface of the heated substrate may react to form an additional portion of the coating. In an embodiment, a reducing gas, such as hydrogen, an inert gas, such as argon, a mixture of inert and reducing gas, may flow into the process chamber after the pellet has been vaporized. In an embodiment, a reactive or carburizing gas, such as methane, may flow into the chamber before or after the pellet has been vaporized. In an embodiment, the components are exposed to the second processing vapor for a period of 1 to 10 minutes, which provides the substrate with time to react with the second processing vapor. In another embodiment, the exposure time may be longer or shorter.

In embodiments in which more than one pellet is dispensed into the processing chamber, the pellets may be dispensed at a desired rate. For example, the pellets may be dispensed at a rate of one pellet every five minutes. In other examples, the pellets may be dispensed more or less frequently. Alternatively, dispensing of the pellets into the processing chamber may depend on a sensed pressure within the chamber.

Method 300 may be used in conjunction with a conventional chemical vapor deposition process. FIG. 4 is a flow diagram of a coating method in which method 300 may be implemented, according to an embodiment. In an embodiment, method 300 is performed, step 402. For example, method 300 may introduce hafnium chloride vapor into the processing chamber where the vapor reacts with the substrate. Before or after step 402, another processing gas, such as aluminum chloride vapor, may be introduced into the processing chamber from an external processing gas source, step 404. In any case, a portion of the processing gas is flowed over the substrate to form a portion of a coating thereon, step 406.

Improved chemical vapor deposition (“CVD”) systems have now been provided. The systems use processing vapor that is formed by vaporization of pellets that may be introduced into the system individually, in a group, in a specific sequence, or in any other tailored manner. The above-described CVD system may be improved over conventional CVD systems, as the improved system does not require external gas generating vapor sources. As a result, the improved CVD systems may be relatively inexpensive to maintain and easier to control. Additionally, because the pellets are maintained separate from the retort until processing, and because the retort chamber and substrate are preheated before processing, the system inhibits formation of undesirable phases as the retort chamber is heated. Vaporization of a sequence of pellets produces a sequence of coating vapor pressure pulses within the processing chamber. In contrast with conventional CVD coaters, which operate at approximately constant pressure, the sequence of pressure pulses within the processing chamber enables internal surfaces of a component to ‘breathe’ coating process vapor and be coated. Thus, improved coatings may be formed using the above-described systems and methods.

While at least one exemplary embodiment has been presented in the foregoing detailed description of the inventive subject matter, it should be appreciated that a vast number of variations exist. It should also be appreciated that the exemplary embodiment or exemplary embodiments are only examples, and are not intended to limit the scope, applicability, or configuration of the inventive subject matter in any way. Rather, the foregoing detailed description will provide those skilled in the art with a convenient road map for implementing an exemplary embodiment of the inventive subject matter. It being understood that various changes may be made in the function and arrangement of elements described in an exemplary embodiment without departing from the scope of the inventive subject matter as set forth in the appended claims.

What is claimed is:

1. A chemical vapor deposition system for coating a substrate, comprising:
a pellet dispenser housing capable of being maintained at a maintenance temperature;
a pellet dispenser disposed within the pellet dispenser housing adapted to receive a first pellet therein, the pellet dispenser configured to dispense the first pellet;
a pellet dispensing conduit in communication with the pellet dispenser and adapted to receive the first pellet therefrom;
a processing chamber in communication with the pellet dispensing conduit, the processing chamber adapted to contain the substrate;
a pressure sensor in flow communication with the processing chamber and adapted to sense a pressure within the processing chamber;
a heater surrounding at least a portion of the processing chamber and adapted to heat the processing chamber and the substrate to a processing temperature that is above the pellet vaporization temperature;
an exhaust conduit in flow communication with the processing chamber including an outlet;
an exhaust valve disposed within the exhaust conduit and adapted to move between a closed position to prevent flow through the outlet and an open position to allow flow through the outlet; and
a controller operatively coupled to the pressure sensor to receive sensed pressure data therefrom and to the valve to supply commands thereto,
wherein:
when the processing chamber pressure is below a threshold pressure, the pellet dispenser dispenses the first pellet into the pellet dispensing conduit and the first pellet is exposed to the processing temperature of the processing chamber, the first pellet changes into a first processing vapor to produce a pressure change in the processing chamber to a first pressure that is above the threshold pressure causing the first processing vapor to flow in the processing chamber and over the substrate,
after a predetermined amount of time, the controller supplies a command to the exhaust valve to move toward the open position, and
when the pressure sensor senses that the pressure is substantially equal to or below the threshold pressure, the controller supplies a command to the exhaust valve to move toward the closed position.

2. The chemical vapor deposition system of claim 1, wherein a portion of the pellet dispensing conduit extends into the processing chamber.

3. The chemical vapor deposition system of claim 1, wherein the threshold pressure is below 0.05 atmosphere.

4. The chemical vapor deposition system of claim 1, further comprising:
an inert or reducing gas source in flow communication with the pellet dispenser housing and processing chamber and adapted to provide an inert or reducing gas thereto.

5. The chemical vapor deposition system of claim 1, further comprising:
a ceramic sponge basket disposed in the processing chamber and adapted to receive a portion of the pellet from the pellet dispensing conduit.

6. The chemical vapor deposition system of claim 1, wherein the pellet dispenser comprises a rotatable carousel including the plurality of wells for containing at least the first pellet.

7. The chemical vapor deposition system of claim 1, wherein the heater comprises a vacuum furnace and the processing chamber is disposed in the vacuum furnace.

8. The chemical vapor deposition system of claim 1, further comprising:
a cold-trap condenser in flow communication with the processing chamber and adapted to receive a portion of the processing vapor from the exhaust conduit.

9. The chemical vapor deposition system of claim 1, wherein the pellet dispenser includes a plurality of pellets and each pellet thereof is substantially identical in formulation.

10. The chemical vapor deposition system of claim 1, wherein the pellet dispenser includes a second pellet that is different in formulation from the first pellet.

11. The chemical vapor deposition system of claim 1, further comprising a valve disposed between the pellet dispenser and the processing chamber.

12. The chemical vapor deposition system of claim further comprising:
an external processing gas source in flow communication with the processing chamber.

13. A method of coating a substrate, the method comprising the steps of:
evacuating a processing chamber to a threshold pressure;
heating a substrate and the processing chamber to a first processing temperature;
dispensing a first pellet into the processing chamber, the first pellet having a vaporization temperature that is below the first processing temperature;
exposing the first pellet to the first processing temperature within the processing chamber that is above the vaporization temperature to vaporize the first pellet into a first processing vapor and to produce a pressure change in the processing chamber from the threshold pressure to a first pressure to cause the first processing vapor to flow through the processing chamber and onto the substrate;
exposing the substrate to the first processing vapor for a predetermined time;
after the step of exposing the substrate, moving a valve in an exhaust conduit in communication with the processing chamber toward an open position; and
moving the valve toward a closed position, when the pressure sensor senses a pressure in the processing chamber is below the threshold pressure.

14. The method of claim 13, further comprising the step of purging and evacuating a portion of the first processing vapor from the processing chamber to decrease a pressure of the processing chamber.

15. The method of claim 13, further comprising the steps of:
dispensing a second pellet into the processing chamber;
vaporizing the second pellet into a second processing vapor when the second pellet is exposed to a second processing temperature which is greater than the vaporization temperature of the second pellet;
producing a pressure change in the processing chamber to cause a portion of the second processing vapor to flow through the processing chamber and onto the substrate.

16. The method of claim 15, wherein the first pellet and the second pellet are substantially similar in formulation.

17. The method of claim 15, wherein the second pellet has a different formulation from the first pellet.

18. The method of claim 13, further comprising the steps of:
introducing a processing gas into the processing chamber from a processing gas source; and
flowing a portion of the processing gas over the substrate to form a second portion of the coating thereon.

19. The method of claim 13, wherein the step of dispensing the first pellet comprises dispensing a pellet comprising a metal halide.

20. The method of claim 19, wherein the step of dispensing a pellet comprises a dispensing a pellet comprising a metal halide selected from the group consisting of hafnium chloride, aluminum chloride, and silicon bromide.
